(19) United States
(12) Patent Application Publication
(10) Pub. No.: US 2026/0362941 A1
(43) Pub. Date: Nov. 12, 2026

(54) DISPLAY DEVICE, AND ELECTRONIC DEVICE USING THE SAME

(71) Applicant: Samsung Display Co., Ltd., Yongin-si (KR)

(72) Inventor: Hyun Eok SHIN, Yongin-si (KR)

(21) Appl. No.: 19/413,755

(22) Filed: Dec. 9, 2025

(30) Foreign Application Priority Data
May 7, 2025 (KR) 10-2025-0058774

(51) Int. Cl. H10K 59/80; H10K 59/12; H10K 59/122; H10K 102/00; H10K 102/10

(52) U.S. Cl. CPC H10K 59/80517; H10K 59/1201; H10K 59/122; H10K 59/80524; H10K 2102/102; H10K 2102/103; H10K 2102/351

(57) ABSTRACT

A display device, a method for manufacturing the display device, and an electronic device including the display device are provided. The display device includes a substrate; an anode electrode on the substrate and including a first layer, a second layer, and a third layer sequentially stacked; a pixel-defining layer covering an edge of the anode electrode and defining a light-emitting opening; a light-emitting layer on the anode electrode and the pixel-defining layer; and a cathode electrode on the light-emitting layer, wherein the first layer of the anode electrode includes aluminum, and the second layer includes molybdenum tantalum oxide.

### CROSS-REFERENCE TO RELATED APPLICATION

The present application claims priority to and the benefit of Korean Patent Application No. 10-2025-0058774, filed on May 7, 2025, in the Korean Intellectual Property Office, the entire disclosure of which is incorporated herein by reference.

### BACKGROUND

### 1. Field

Embodiments of the present disclosure relate to a display device and an electronic device including the same.

### 2. Description of the Related Art

In general, flat panel display devices, such as liquid crystal display displays and/or organic light-emitting display displays, may include a plurality of pairs of electric field generating electrodes and an electro-optical active layer arranged therebetween. A liquid crystal display device may include a liquid crystal layer as the electro-optical active layer, and a organic light-emitting display device may include an organic light-emitting layer as the electro-optical active layer.

In general, organic light-emitting display devices are capable of implementing color due to the phenomenon in which holes and electrons injected from anode and cathode electrodes recombine in a light-emitting portion to emit light, and thus organic light-emitting display devices may have a stacked structure in which a light-emitting layer is inserted between the anode and cathode electrodes to form one or more pixels.

Recently, pixels have been developed that include a resonant structure to improve the light extraction efficiency of the organic light-emitting display device. The resonant structure may provide for constructive interference to occur as light travels back and forth between the anode and cathode electrodes by configuring one side among the anode and cathode electrodes where an image is implemented as a semi-transmissive electrode, and configuring an opposite side as a reflective electrode. This configuration may enhance the intensity of the light extracted from each pixel.

However, when applying the resonance structure described above, instead of increasing the light extraction efficiency, there may be a disadvantage in that the light’s viewing angle may be reduced (e.g., the light’s straightness may become too strong, resulting in poor viewing angle characteristics). For example, when the resonance structure is used, a luminance deviation based on a viewing angle may occur.

The above information disclosed in this Background section is intended to enhance understanding of the background of the disclosure and may contain information that does not constitute prior art.

### SUMMARY

Aspects of one or more embodiments of the present disclosure are directed to a high-quality display device having improved luminance uniformity across a viewing angle (e.g., a decreased luminance deviation).

Aspects of one or more embodiments of the present disclosure are directed to an electronic device including the same.

However, aspects of the present disclosure are not limited to those set forth above. Additional aspects will be set forth in part in the description which follows and, in part, will be apparent from the description, or may be learned by practice of the presented embodiments of the disclosure.

Details of one or more embodiments are included in the detailed description and drawings.

According to one or more embodiments of the present disclosure, a display device includes a substrate; an anode electrode positioned on the substrate and including a first layer, a second layer, and a third layer sequentially stacked; a pixel-defining layer covering an edge of the anode electrode and defining a light-emitting opening; a light-emitting layer positioned on the anode electrode and the pixel-defining layer; and a cathode electrode positioned on the light-emitting layer, wherein the first layer of the anode electrode includes aluminum, and the second layer includes molybdenum tantalum oxide.

In one or more embodiments, an atomic percentage of tantalum included in the second layer may be about 10 at% or more and about 12 at% or less (e.g., may be in a range of 10 at% to 12 at%).

In one or more embodiments, the second layer may have a reflectivity of about 10% or less in a visible light range of about 380 nanometers or more and about 700 nanometers or less (e.g., in a visible light range of 380 nanometers to 700 nanometers).

In one or more embodiments, the third layer may be in contact with and on the second layer, and the third layer includes indium tin oxide.

In one or more embodiments, the third layer may have a transmittance of about 80% or more in the visible light range of 380 nanometers or more and about 700 nanometers or less (e.g., in a visible light range of 380 nanometers to 700 nanometers).

In one or more embodiments, the anode electrode may have a structure in which aluminum, molybdenum tantalum oxide, and indium tin oxide are in contact with each other and stacked.

In one or more embodiments, the pixel-defining layer may include a black dye or a black pigment.

In one or more embodiments, the pixel-defining layer may be in contact with the third layer of the anode electrode, and the third layer is in contact with the light-emitting layer at a portion overlapping the light-emitting opening.

In one or more embodiments, a side surface of the first layer, a side surface of the second layer, and a side surface of the third layer may be in contact with and covered by the pixel-defining layer.

In one or more embodiments, the side surface of the first layer and the side surface of the second layer may be positioned on the same line.

In one or more embodiments, the cathode electrode may include a transparent conductive material, and the cathode electrode has a transmittance of about 80% or more in a visible light range of about 380 nanometers or more and about 700 nanometers or less (e.g., in a visible light range of 380 nanometers to 700 nanometers).

In one or more embodiments, the second layer may have a resistivity value of 1.0x10⁴ μΩ·cm (i.e., 1×10⁻² Ω·cm) or less.

In one or more embodiments, the anode electrode may have a thickness of about 450 Angstroms or more and about 800 Angstroms or less (e.g., may have a thickness of 450 Angstroms to 800 Angstroms).

According to one or more embodiments of the disclosure, a method for manufacturing a display device includes: forming a first layer, a second layer, and a third layer of an anode electrode; removing a portion of the third layer by performing a wet etching process; and removing a portion of the first layer and the second layer by performing a dry etching process, wherein the first layer includes aluminum, the second layer includes molybdenum tantalum oxide, and the third layer includes indium tin oxide.

In one or more embodiments, in the removing of the portion of the first layer and the second layer by performing the dry etching process, the first layer and the second layer may be removed concurrently (e.g., simultaneously or at once), and a side surface of the first layer and a side surface of the second layer are positioned on the same line.

According to one or more embodiments of the present disclosure, an electronic device includes: at least one display device including a substrate; and at least one of a display module, a processor, a memory, or a power module connected to the display device, wherein the at least one display device includes: an anode electrode positioned on the substrate and including a first layer, a second layer, and a third layer sequentially stacked; a pixel-defining layer covering an edge of the anode electrode and defining a light-emitting opening; a light-emitting layer positioned on the anode electrode and the pixel-defining layer; and a cathode electrode positioned on the light-emitting layer, wherein the first layer of the anode electrode includes aluminum, and the second layer includes molybdenum tantalum oxide.

The display device and the electronic device including the same according to one or more embodiments may improve luminance deviation (i.e., may reduce luminance deviation) based on the viewing angle by including the anode electrode including a material having low-reflection characteristics, the pixel-defining layer having high light absorption characteristics, and the transparent cathode electrode. Therefore, the electronic device including the display device according to one or more embodiments may implement high-quality display characteristics. In addition, for example, one or more embodiments may further provide that the second layer of the anode electrode exhibits a resistivity of about 1.0×10⁴ μΩ·cm or less and a reflectivity of about 10% or less within the visible light range of about 380 nm to about 700 nm, while the third layer maintains a transmittance of about 80% or more in the same range. These characteristics, combined with the stacked structure of aluminum, molybdenum tantalum oxide, and indium tin oxide, and the pixel-defining layer comprising a black pigment or dye, enable the display device to achieve reduced luminance deviation across wide viewing angles without requiring a resonant cavity structure. Accordingly, the electronic device incorporating such a display device may deliver high-quality image performance with improved angular uniformity and simplified manufacturing processes.

However, the aspects/effects of the present disclosure are not restricted to the ones set forth herein. The above and other aspects/effects of the embodiments will become more apparent to one of ordinary skill in the art to which the present disclosure pertains by referencing the claims.

### BRIEF DESCRIPTION OF THE DRAWINGS

The accompanying drawings are included to provide a further understanding of the present disclosure and are incorporated in and constitute a part of this specification. The drawings illustrate example embodiments of the present disclosure and, together with the description, serve to explain principles of the present disclosure. In the drawings

FIG. 1 is a perspective view illustrating a display device according to one or more embodiments of the present disclosure;

FIG. 2 is a schematic cross-sectional view of the display device of FIG. 1, according to one or more embodiments of the present disclosure;

FIG. 3 is a plan view illustrating an arrangement of light-emitting areas in a display area of FIG. 2, according to one or more embodiments of the present disclosure;

FIG. 4 is a schematic cross-sectional view taken along the line X1-X1’ of FIG. 3, according to one or more embodiments of the present disclosure;

FIG. 5 is a schematic cross-sectional view of a light-emitting layer according to one or more embodiments of the present disclosure;

FIG. 6 is a schematic cross-sectional view of a light-emitting layer according to one or more embodiments of the present disclosure;

FIG. 7 is an enlarged cross-sectional view of the area A in FIG. 4, according to one or more embodiments of the present disclosure;

FIG. 8 is an enlarged cross-sectional view of the area A in FIG. 4 of a comparative example;

FIG. 9 is a graph illustrating light reflectivity based on a thickness of an anode electrode according to one or more embodiments of the present disclosure;

FIG. 10 is a graph illustrating a ratio of efficiency for each side angle relative to frontal efficiency of the display device according to one or more embodiments of the present disclosure;

FIG. 11 is a flowchart illustrating a method for manufacturing an anode electrode according to one or more embodiments of the present disclosure;

FIG. 12 is a cross-sectional view for describing step (e.g., act or task) S100 of FIG. 11 according to one or more embodiments of the present disclosure;

FIGS. 13 and 14 are cross-sectional views for describing step (e.g., act or task) S200 of FIG. 11 according to one or more embodiments of the present disclosure;

FIGS. 15 and 16 are cross-sectional views for describing step (e.g., act or task) S300 of FIG. 11 according to one or more embodiments of the present disclosure;

FIG. 17 is a block diagram of an electronic device according to one or more embodiments; and

FIG. 18 illustrates schematic diagrams of electronic devices according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on” or “connected to” another element, it can be directly on or connected to the other element, or one or more intervening elements may be present. In contrast, when an element or layer is referred to as being “directly on,” “directly connected to”, or “immediately adjacent to” another element or layer, there are no intervening elements or layers present. In addition, it will also be understood that when an element is referred to as being “between” two elements, it can be the only element between the two elements, or one or more intervening elements may also be present.

Unless otherwise noted, like reference numerals denote like elements throughout the attached drawings and the written description, and thus, duplicative descriptions thereof may not be provided.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “on,” “below,” “lower,” “under,” “above,” “upper,” and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

As used herein, the singular forms “a,” “an” and “the” are intended to include the plural forms as well, unless the context clearly indicates otherwise. It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions "at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

In the drawings, the relative sizes (e.g., including lengths, widths and thicknesses) of elements, layers, and regions may be exaggerated for clarity.

Unless otherwise defined, all terms (including technical and scientific terms) used herein have the same meaning as commonly understood by one of ordinary skill in the art to which the present disclosure pertains. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, embodiments of the present disclosure will be described in more detail with reference to the accompanying drawings.

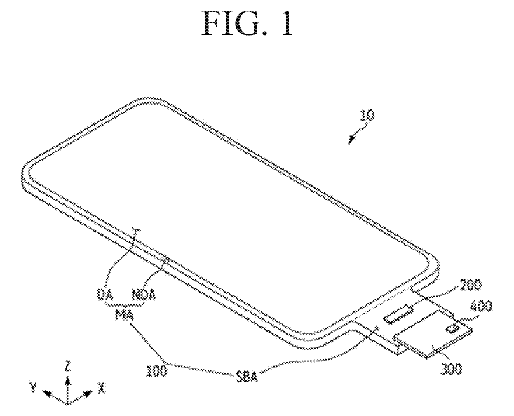

FIG. 1 is a perspective view illustrating a display device according to one or more embodiments of the present disclosure.

Referring to FIG. 1, a display device 10 may display a moving image and/or a still image. The display device 10 may refer to any electronic device that provides a display screen. For example, the display device 10 may include a television, a laptop computer, a monitor, a billboard, an Internet of thing, a mobile phone, a smartphone, a tablet personal computer (PC), an electronic watch, a smartwatch, a watch phone, a head-mounted display, a mobile communication terminal, an electronic notebook, an electronic book, a portable multimedia player (PMP), a navigation system, a game console, a digital camera, a camcorder, and/or the like that provides the display screen.

In FIG. 1, a first direction (X-axis direction), a second direction (Y-axis direction), and a third direction (Z-axis direction) are defined. The first direction (X-axis direction) and the second direction (Y-axis direction) may be normal (e.g., perpendicular) to each other, the first direction (X-axis direction) and the third direction (Z-axis direction) may be normal (e.g., perpendicular) to each other, and the second direction (Y-axis direction) and the third direction (Z-axis direction) may be normal (e.g., perpendicular) to each other. It may be understood that, in plan view, e.g., a top down view showing the layout and spatial relationships of various elements within the object or structure, the first direction (X-axis direction) refers to a horizontal direction in the drawings, the second direction (Y-axis direction) refers to a vertical direction in the drawings, and the third direction (Z-axis direction) refers to a direction from the top down, that is, a thickness direction. In the following specification, unless otherwise specified, the term “direction” may refer to both directions toward opposite sides extending along the direction. In addition, when both “directions” extending to the opposite sides need to be distinguished from each other, one side will be referred to as “one side in the direction” and the other side will be referred to as “the other side in the direction”. In FIG. 1, a direction in which an arrow indicating a direction is directed is referred to as one side, and an opposite direction thereof is referred to as the other side.

Hereinafter, for convenience of explanation, in referring to surfaces of each member constituting the display device 10, one surface facing one side in a direction in which an image is displayed, that is, in the third direction (Z-axis direction) is referred to as an upper surface, and an opposite surface of the one surface is referred to as the other surface. However, the present disclosure is not limited thereto, and the one surface and the other surface of the member may be referred to as a front surface and a rear surface, respectively, or may also be referred to as a first surface or a second surface. In addition, in describing a relative position of each member of the display device 10, one side in the third direction (Z-axis direction) may be referred to as an upper side and the other side in the third direction (Z-axis direction) may be referred to as a lower side.

A shape of the display device 10 may be variously changed. For example, the display device 10 may have a shape such as a rectangle with a long width, a rectangle with a long length, a square, a quadrangle with rounded corners (vertices), other polygons, or a circle.

The display device 10 may include a display panel 100, a display driver 200, a circuit board 300, and a touch driver 400.

The display panel 100 may include a main area MA and a sub-area SBA. The main area MA may include a display area DA including pixels displaying an image and a non-display area NDA arranged around the display area DA. The main area MA and the sub-area SBA may include a flexible material that may be bent, folded, rolled, and/or the like.

The display area DA is an area in which a screen may be displayed, and the non-display area NDA is an area in which a screen is not displayed. The display area DA may also be referred to as an active area, and the non-display area NDA may be referred to as a non-active area. The display area DA may generally occupy the center of the display device 10. The non-display area NDA may be an area outside the display area DA. The non-display area NDA may be defined by or as an edge area of the main area MA of the display panel 100. The non-display area NDA may include lines that supply signals to the display area DA and lines connecting the display driver 200 and the display area DA.

The sub-area SBA may be an area extending from one side of the main area MA. When the sub-area SBA is bent, the sub-area SBA may overlap the main area MA in a thickness direction (e.g., a third direction (Z-axis direction)). The sub-area SBA may include the display driver 200 and a display pad connected to the circuit board 300. In one or more embodiments, the sub-area SBA may not be provided, and the display driver 200 and the display pad may be positioned in the non-display area NDA.

The display driver 200 may output signals and voltages for driving the display panel 100. The display driver 200 may be formed as an integrated circuit (IC) and mounted on the display panel 100 by a chip on glass (COG) method, a chip on plastic (COP) method, or an ultrasonic bonding method. For example, the display driver 200 may be arranged in the sub-area SBA, and may overlap the main area MA in the thickness direction by bending the sub-area SBA. As another example, the display driver 200 may be mounted on the circuit board 300.

The circuit board 300 may be attached onto the display pad of the display panel 100 using an anisotropic conductive film (ACF). The circuit board 300 may be electrically connected to the display pad. The circuit board 300 may be a flexible film such as a flexible printed circuit board, a printed circuit board, or a chip on film.

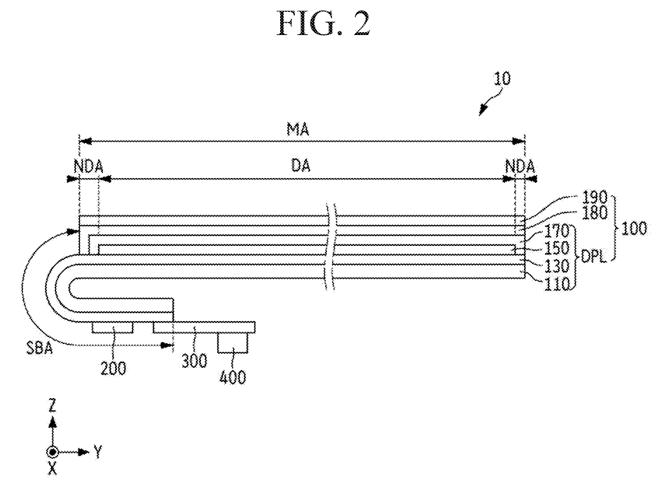

The touch driver 400 may be mounted on the circuit board 300. The touch driver 400 may be connected to a touch sensor layer (see, e.g., the touch sensor layer 180 of FIG. 2) of the display panel 100.

FIG. 2 is a schematic cross-sectional view of the display device of FIG. 1, according to one or more embodiments of the present disclosure.

Referring to FIG. 2, the display panel 100 may include a display layer DPL, a touch sensor layer 180, and a color filter layer 190. The display layer DPL may include a substrate 110, a thin film transistor layer 130, a display element layer 150, and a thin film encapsulation layer 170.

The substrate 110 may be a base substrate or a base member. The substrate 110 may be a flexible substrate that may be bent, folded, rolled, and/or the like. For example, the substrate 110 may include a polymer resin such as polyimide PI, but the present disclosure is not limited thereto. In one or more embodiments, the substrate 110 may include a glass material or a metal material.

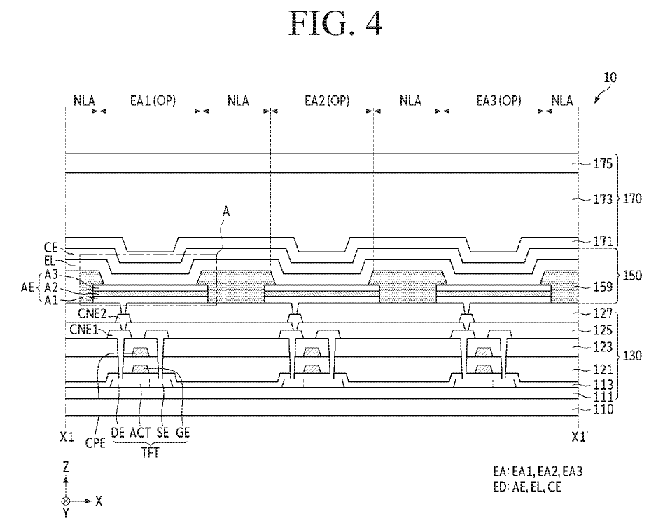

The thin film transistor layer 130 may be positioned on the substrate 110. The thin film transistor layer 130 may be positioned in a portion overlapping the display area DA, the non-display area NDA, and the sub-area SBA. The thin film transistor layer 130 may include a plurality of thin film transistors (see, e.g., the thin film transistor TFT of FIG. 4).

The display element layer 150 may be positioned on the thin film transistor layer 130. The display element layer 150 may be positioned in a portion overlapping the display area DA. The display element layer 150 may include, but is not limited to, at least one of an organic light-emitting diode (LED) including an organic light-emitting layer, a quantum dot LED including a quantum dot light-emitting layer, an inorganic LED including an inorganic semiconductor, or a micro LED.

The thin film encapsulation layer 170 may be positioned on the display element layer 150. The thin film encapsulation layer 170 may be positioned in a portion overlapping the display area DA and the non-display area NDA. The thin film encapsulation layer 170 may cover an upper surface and side surfaces of the display element layer 150, and may protect the display element layer 150 from external oxygen and moisture. The thin film encapsulation layer 170 may include at least one inorganic film and at least one organic film for encapsulating the display element layer 150.

The touch sensor layer 180 may be positioned on the thin film encapsulation layer 170. The touch sensor layer 180 may be positioned in a portion overlapping the display area DA and the non-display area NDA. The touch sensor layer 180 may sense a user’s touch in a mutual capacitance method or a self-capacitance method.

The color filter layer 190 may be positioned on the touch sensor layer 180. The color filter layer 190 may be positioned in a portion overlapping the display area DA and the non-display area NDA. The color filter layer 190 may be to absorb a portion of light introduced from the outside of the display device 10 to reduce reflected light caused by external light. Therefore, the color filter layer 190 may prevent or reduce color distortion caused by reflection of external light.

As the color filter layer 190 is directly arranged on the touch sensor layer 180, the display device 10 may not require a separate substrate for the color filter layer 190. Therefore, the display device 10 may have a relatively small thickness. In some embodiments, the color filter layer 190 may not be provided.

As illustrated in FIG. 2, a portion of the display layer DPL overlapping the sub-area SBA may be bent. When a portion of the display layer DPL is bent, the display driver 200, circuit board 300, and touch driver 400 may overlap the main area MA in the third direction (Z-axis direction).

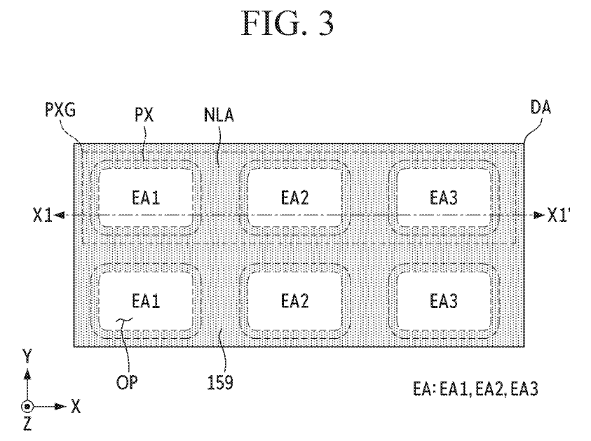

FIG. 3 is a plan view illustrating an arrangement of light-emitting areas in a portion of the display area DA of FIG. 2, according to one or more embodiments of the present disclosure.

Referring to FIG. 3, the display area DA according to one or more embodiments may include a light-emitting area EA and a non-light-emitting area NLA. The non-light-emitting area NLA may be positioned to be around (e.g., surround) each of the first to third light-emitting areas EA1, EA2, and EA3.

The non-light-emitting area NLA may block or reduce light emitted from each of the first to third light-emitting areas EA1, EA2, and EA3. As a result, the non-light-emitting area NLA may assist in preventing or reducing the light emitted from each of the first to third light-emitting areas EA1, EA2, and EA3 from being mixed in the non-light-emitting area NLA between the first to third light-emitting areas EA1, EA2, and EA3.

The light-emitting area EA may include a first light-emitting area EA1, a second light-emitting area EA2, and a third light-emitting area EA3 that emit light of different colors. Each of the first to third light-emitting areas EA1, EA2, and EA3 may each emit red, green, or blue light, respectively, and the color of light emitted from each of the first to third light-emitting areas EA1, EA2, and EA3 may vary depending on the type (kind) of light-emitting element (see, e.g., the light-emitting element ED of FIG. 4), which will be described in more detail later. It is illustrated in the drawing that the size and shape of each of the first to third light-emitting areas EA1, EA2, and EA3 are the same, but the present disclosure is not limited thereto. The size and shape of each of the first to third light-emitting areas EA1, EA2, and EA3 may be freely adjusted according to desired or required characteristics.

At least one first light-emitting area EA1, at least two second light-emitting areas EA2, and at least one third light-emitting area EA3 arranged to be adjacent to each other may form one pixel group PXG. The pixel group PXG may be a minimum unit that emits white light. However, the type (kind) and/or number of the first to third light-emitting areas EA1, EA2, and EA3 constituting the pixel group PXG may vary depending on the embodiments.

In plan view, the pixel-defining layer 159 may overlap a portion of the light-emitting area EA and a portion of the non-light-emitting area NLA. In plan view, the pixel-defining layer 159 may define a light-emitting opening OP. In plan view, the pixel-defining layer 159 may be positioned to be around (e.g., surround) the light-emitting opening OP.

FIG. 4 is a schematic cross-sectional view taken along the line X1-X1’ of FIG. 3, according to one or more embodiments of the present disclosure. FIG. 4 is a cross-sectional view of a portion of the display device overlapping the display area of FIG. 3, which illustrates a schematic cross-section of a portion of the display layer. For example, FIG. 4 illustrates a cross-section of a substrate, a thin film transistor layer, a display element layer, and a thin film encapsulation layer positioned in a portion overlapping the display area (e.g., the display area DA of FIG. 3) included in the display device 10. Because the substrate 110 has already been described, a repeated description thereof may not be provided.

Referring to FIG. 4 in addition to FIGS. 1-3, the thin film transistor layer 130 may be positioned on the substrate 110. The thin film transistor layer 130 may include a first buffer layer 111, a thin film transistor TFT, a gate insulating layer 113, a first interlayer insulating layer 121, a capacitor electrode CPE, a second interlayer insulating layer 123, a first connection electrode CNE1, a first via layer 125, a second connection electrode CNE2, and a second via layer 127.

The first buffer layer 111 may be positioned on the substrate 110. The first buffer layer 111 may include an inorganic film capable of preventing or reducing permeation of air or moisture. For example, the first buffer layer 111 may include a plurality of inorganic films alternately stacked.

The thin film transistor TFT may be arranged on the first buffer layer 111, and may constitute a part of a pixel circuit, where the display device 10 may include a plurality of pixel circuits and each of the plurality of pixel circuits is connected to a respective one of the plurality of pixels. As an example, the thin film transistor TFT may be a driving transistor or a switching transistor of the pixel circuit. The thin film transistor TFT may include an active layer ACT, a source electrode SE, a drain electrode DE, and a gate electrode GE.

The active layer ACT may be positioned on the first buffer layer 111. The active layer ACT may overlap the gate electrode GE in the third direction (Z-axis direction), and may be insulated from the gate electrode GE by the gate insulating layer 113. In a portion of the active layer ACT, a material of the active layer ACT may become a conductor to form the source electrode SE and the drain electrode DE.

The gate electrode GE may be positioned on the gate insulating layer 113. The gate electrode GE may overlap the active layer ACT with the gate insulating layer 113 therebetween.

The gate insulating layer 113 may be positioned on the active layer ACT. The gate insulating layer 113 may cover the active layer ACT and the first buffer layer 111, and may insulate the active layer ACT and the gate electrode GE from each other. The gate insulating layer 113 may include a contact hole through which the first connection electrode CNE1 penetrates.

The first interlayer insulating layer 121 may cover the gate electrode GE and the gate insulating layer 113. The first interlayer insulating layer 121 may include a contact hole through which the first connection electrode CNE1 penetrates. The contact hole of the first interlayer insulating layer 121 may be connected to the contact hole of the gate insulating layer 113 and a contact hole of the second interlayer insulating layer 123.

The capacitor electrode CPE may be positioned on the first interlayer insulating layer 121. The capacitor electrode CPE may overlap the gate electrode GE in the third direction (Z-axis direction). The capacitor electrode CPE and the gate electrode GE may form a capacitance.

The second interlayer insulating layer 123 may cover the capacitor electrode CPE and the first interlayer insulating layer 121. The second interlayer insulating layer 123 may include a contact hole through which the first connection electrode CNE1 penetrates. The contact hole of the second interlayer insulating layer 123 may be connected to the contact hole of the first interlayer insulating layer 121 and the contact hole of the gate insulating layer 113.

The first connection electrode CNE1 may be positioned on the second interlayer insulating layer 123. The first connection electrode CNE1 may electrically connect the drain electrode DE of the thin film transistor TFT and the second connection electrode CNE2 to each other. The first connection electrode CNE1 may be inserted into the contact holes formed in the first interlayer insulating layer 121, the second interlayer insulating layer 123, and the gate insulating layer 113 and be in contact with the drain electrode DE of the thin film transistor TFT.

The first via layer 125 may cover the first connection electrode CNE1 and the second interlayer insulating layer 123. The first via layer 125 may planarize a lower structure. The first via layer 125 may include a contact hole through which the second connection electrode CNE2 penetrates.

The second connection electrode CNE2 may be positioned on the first via layer 125. The second connection electrode CNE2 may be inserted into the contact hole formed in the first via layer 125 and be in contact with the first connection electrode CNE1. The second connection electrode CNE2 may electrically connect the first connection electrode CNE1 and an anode electrode AE to each other.

The second via layer 127 may cover the second connection electrode CNE2 and the first via layer 125. The second via layer 127 may include a contact hole through which the anode electrode AE penetrates.

The display element layer 150 may be positioned on the second via layer 127. The display element layer 150 may include a light-emitting element ED and a pixel-defining layer 159. The light-emitting element ED may include an anode electrode AE, a light-emitting layer EL, and a cathode electrode CE.

The anode electrode AE may be positioned on the second via layer 127. The anode electrode AE may be electrically connected to the drain electrode DE of the thin film transistor TFT through the first and second connection electrodes CNE1 and CNE2.

The anode electrode AE may be formed in plural, and the plurality of anode electrodes AE may be spaced and/or apart (e.g., spaced apart or separated) from each other and may be positioned in a portion overlapping each of the first to third light-emitting areas EA1, EA2, and EA3.

The anode electrode AE may include a first layer A1, a second layer A2, and a third layer A3 that are sequentially stacked. The first layer A1, the second layer A2, and the third layer A3 may include different materials. Details will be described in more detail later.

The pixel-defining layer 159 may be positioned on the second via layer 127 in a portion overlapping the non-light-emitting area NLA. The pixel-defining layer 159 may define the light-emitting opening OP and expose the anode electrode AE in a portion overlapping the light-emitting opening OP. The pixel-defining layer 159 may cover an edge of the anode electrode AE.

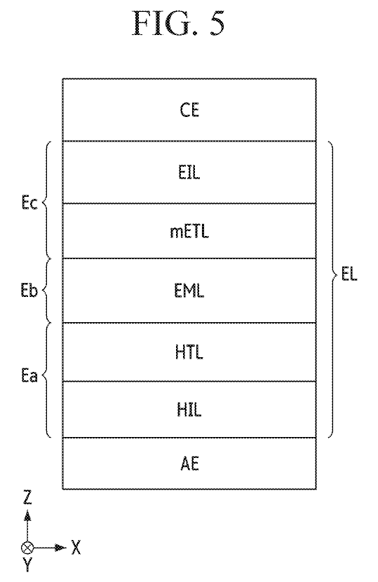

FIG. 5 is a schematic cross-sectional view of a light-emitting layer according to one or more embodiments of the present disclosure.

Referring to FIGS. 4 and 5, the light-emitting layer EL may be positioned on the anode electrode AE. The light-emitting layer EL according to one or more embodiments may include a first portion Ea, a second portion Eb, and a third portion Ec that are sequentially stacked in the third direction (Z-axis direction).

The first portion Ea may be positioned in contact with the anode electrode AE, the third portion Ec may be positioned in contact with the cathode electrode CE, and the second portion Eb may be positioned between the first portion Ea and the third portion Ec.

In one or more embodiments, the first portion Ea of the light-emitting layer EL may include a hole injection layer HIL and a hole transporting layer HTL. The hole injection layer HIL may be positioned on the anode electrode AE, and the hole transporting layer HTL may be positioned on the hole injection layer HIL. Depending on the embodiment, the hole injection layer HIL and the hole transporting layer HTL may be formed as one layer to form a hole injection and transporting layer.

The hole injection layer HIL may assist in injecting (e.g., smoothly injecting) holes from the anode electrode AE to the organic light-emitting layer EML. The hole injection layer HIL may have a single layer made of a single material, a single layer made of a plurality of different materials, or a multilayer structure having a plurality of layers each made of different materials. The hole injection layer HIL according to one or more embodiments may include materials generally available and/or generally used in the art.

The hole transporting layer HTL may assist in transporting (e.g., smoothly transporting) holes from the anode electrode AE to the organic light-emitting layer EML. The hole transporting layer HTL may have a single layer made of a single material, a single layer made of a plurality of different materials, or a multilayer structure having a plurality of layers each made of different materials. The hole transporting layer HTL according to one or more embodiments may include any suitable material(s) generally available and/or generally used in the art.

The second portion Eb of the light-emitting layer EL may include an organic light-emitting layer EML. The organic light-emitting layer EML serves to emit light by combining electrons and holes. The light emitted from the organic light-emitting layer EML may be emitted in all directions.

The organic light-emitting layer EML may include a host material and a dopant material. The organic light-emitting layer EML may be to emit light by combining the host material and the dopant material, using a phosphorescent or fluorescent-emitting material as a dopant in the host material.

The third portion Ec may include an electron transporting layer mETL and an electron injection layer EIL.

The electron injection layer EIL may serve to inject electrons transferred from the cathode electrode CE to the light-emitting layer EL. The electron injection layer EIL according to one or more embodiments may include any suitable material(s) generally available and/or generally used in the art.

The electron transporting layer mETL may serve to transport electrons transferred from the cathode electrode CE to the light-emitting layer EL. The electron transporting layer mETL according to one or more embodiments may include any suitable material(s) generally available and/or generally used in the art.

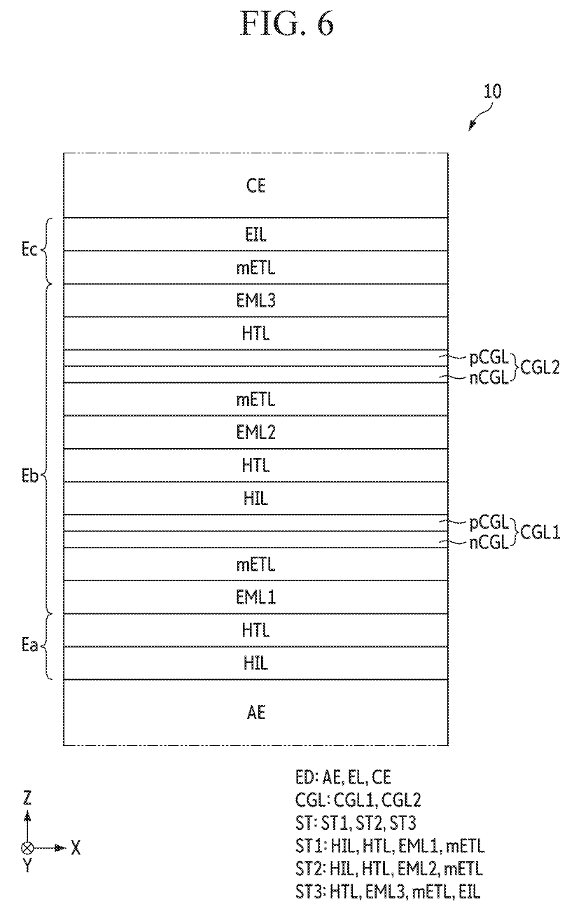

FIG. 6 is a schematic cross-sectional view of a light-emitting layer according to one or more embodiments of the present disclosure.

Referring to FIGS. 4 and 6, in one or more embodiments, the light-emitting layer EL may include a plurality of light-emitting stacks ST. The light-emitting stack ST may include a polymer or small molecule organic material that emits light of a selected color. The light-emitting stack ST may further include, in addition to one or more suitable organic materials, inorganic materials, such as metal-containing compounds such as organometallic compounds and/or quantum dots. It is illustrated in the drawing that the light-emitting layer EL is a three (3) tandem structure including three light-emitting stacks ST, but the present disclosure is not limited thereto. The light-emitting layer EL may also include two or fewer light-emitting stacks ST, or four or more light-emitting stacks ST.

The light-emitting stack ST may include a plurality of organic light-emitting layers EML. For example, a first light-emitting stack ST1 may include a first organic light-emitting layer EML1, a second light-emitting stack ST2 may include a second organic light-emitting layer EML2 overlapping the first organic light-emitting layer EML1, and a third light-emitting stack ST3 may include a third organic light-emitting layer EML3 overlapping the first organic light-emitting layer EML1 and the second organic light-emitting layer EML2.

For example, the first organic light-emitting layer EML1 may be to emit any one of light of a first color, light of a second color, or light of a third color, the second organic light-emitting layer EML2 may be to emit any one of light of a first color, light of a second color, or light of a third color, and the third organic light-emitting layer EML3 may be to emit any one of light of a first color, light of a second color, or light of a third color. Depending on one or more embodiments, the first organic light-emitting layer EML1, the second organic light-emitting layer EML2, and/or the third organic light-emitting layer EML3 may also emit light of the same color or may also emit light of different colors. For example, the light of the first color may be red light, the light of the second color may be green light, and the light of the third color may be blue light, but the present disclosure is not limited thereto.

The light-emitting stack ST may further include at least one intermediate layer overlapping at least one organic light-emitting layer EML. As an example, the intermediate layer may include a hole injection layer HIL, a hole transporting layer HTL, an electron transporting layer mETL, and/or an electron injection layer EIL. As these features are described above with reference to FIG. 5, redundant descriptions thereof may not be provided.

The light-emitting stack ST may further include a charge generation layer CGL positioned between the plurality of organic light-emitting layers EML. The charge generation layer CGL may be a functional layer that controls charge balance between the respective light-emitting stacks ST. Therefore, the charge generation layer CGL may increase a light-emitting efficiency of the light-emitting element ED and lower a driving voltage thereof by providing charges to each of the first to third organic light-emitting layers EML1, EML2, and EML3.

The charge generation layer CGL may include a first charge generation layer CGL1 positioned between the first light-emitting stack ST1 and the second light-emitting stack ST2, and a second charge generation layer CGL2 positioned between the second light-emitting stack ST2 and the third light-emitting stack ST3.

A negative charge generation layer nCGL included in the first charge generation layer CGL1 may be arranged in contact with the first light-emitting stack ST1 to supply electrons to the first organic light-emitting layer EML1 and may include a host and a dopant. The host may include an organic material, and the dopant may include a metallic material. In one or more embodiments, the negative charge generation layer nCGL may include any suitable material(s) generally available and/or generally used in the art for the negative charge generation layer nCGL.

A positive charge generation layer pCGL included in the first charge generation layer CGL1 may be arranged in contact with the second light-emitting stack ST2 to supply holes to the second organic light-emitting layer EML2 and may include a host and a dopant. The host may include an organic material, and the dopant may include a metallic material. In one or more embodiments, the positive charge generation layer pCGL may include any suitable material(s) generally available and/or generally used in the art for the positive charge generation layer pCGL.

A negative charge generation layer nCGL included in the second charge generation layer CGL2 may be arranged in contact with the second light-emitting stack ST2 to supply electrons to the second organic light-emitting layer EML2, and a positive charge generation layer pCGL included in the second charge generation layer CGL2 may be arranged in contact with the third light-emitting stack ST3 to supply electrons to the third organic light-emitting layer EML3.

In one or more embodiments, the first portion Ea of the light-emitting layer EL may include a hole injection layer HIL and a hole transporting layer HTL of the first light-emitting stack ST1, and the third portion Ec thereof may include an electron transporting layer mETL and an electron injection layer EIL of the third light-emitting stack ST3. In addition, the second portion Eb of the light-emitting layer EL may include a first organic light-emitting layer EML1 and an electron transporting layer mETL of the first light-emitting stack ST1, a hole transporting layer HTL and a third organic light-emitting layer EML3 of the third light-emitting stack ST3 and the second light-emitting stack ST2.

The cathode electrode CE may be positioned on the light-emitting layer EL. The cathode electrode CE may be entirely formed on the light-emitting layer EL (e.g., the cathode electrode CE may be formed across an entirety of the light-emitting layer EL) and may be a common electrode.

In general, making each pixel into a resonant structure may improve a light extraction efficiency of the organic light-emitting display device. The resonant structure uses a method in which constructive interference occurs as light travels back and forth between the anode electrode AE and the cathode electrode CE by configuring one side among the anode electrode AE and the cathode electrode CE where an image is implemented as a semi-transmissive electrode, and configuring an opposite side as a reflective electrode, and accordingly, enhanced light or improved light intensity may be extracted from each pixel.

However, when applying the resonance structure, instead of only increasing the light extraction efficiency, there may be a disadvantage in that direction of light emitted from the display device becomes too linear (e.g., the light’s straightness becomes too strong), decreasing the viewing angle. For example, when the resonance structure is used, a luminance deviation based on the viewing angle may occur. Details will be described in more detail later.

The thin film encapsulation layer 170 may be positioned on the display element layer 150. The thin film encapsulation layer 170 may be positioned in a portion overlapping the light-emitting area EA and the non-light-emitting area NLA. The thin film encapsulation layer 170 may include a first encapsulation layer 171, a second encapsulation layer 173, and a third encapsulation layer 175 that are sequentially stacked.

The first encapsulation layer 171 may be positioned on the cathode electrode CE. The first encapsulation layer 171 may have a substantially uniform thickness according to a profile of a lower structure (e.g., the layers below the first encapsulation layer 171) and may cover the lower structure. Therefore, the first encapsulation layer 171 may include a step difference. For example, the first encapsulation layer 171 may have a substantially uniform thickness and may follow the profile of the topography created by the display and pixel circuit layers 150, 170 below the first encapsulation layer 171.

The first encapsulation layer 171 may include one or more inorganic insulating materials and may prevent or reduce the likelihood of oxygen or moisture permeating into the light-emitting element ED. As an example, the first encapsulation layer 171 may include any one of aluminum oxide, titanium oxide, tantalum oxide, hafnium oxide, zinc oxide, silicon oxide, silicon nitride, and/or silicon oxynitride.

The second encapsulation layer 173 may be positioned on the first encapsulation layer 171. The second encapsulation layer 173 may planarize the step difference formed by the first encapsulation layer 171. In one or more embodiments, the second encapsulation layer 173 may protect the display element layer 150 from foreign substances.

The second encapsulation layer 173 may include a polymer-based material. As an example, the second encapsulation layer 173 may include a silicon-based resin, an acrylic-based resin, an epoxy-based resin, and/or a (e.g., any suitable) mixture thereof.

The third encapsulation layer 175 may be positioned on the second encapsulation layer 173. The third encapsulation layer 175 may include one or more inorganic insulating materials and may prevent or reduce the likelihood of oxygen or moisture permeating into the display element layer 150 and the first encapsulation layer 171. The third encapsulation layer 175 may include the same material as the first encapsulation layer 171.

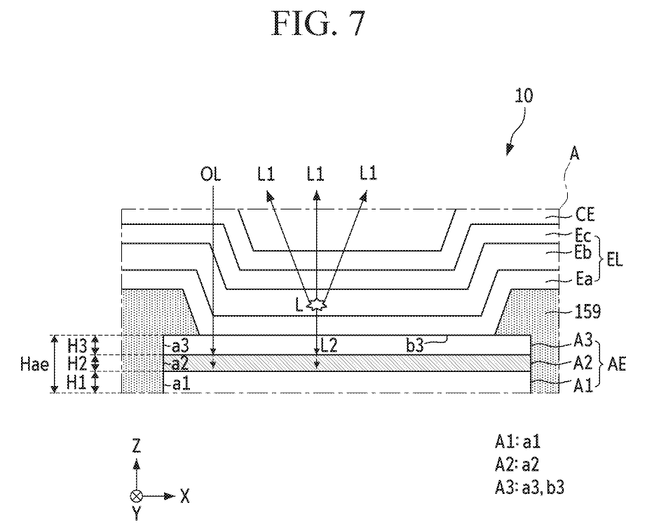

FIG. 7 is an enlarged cross-sectional view of the area A in FIG. 4, according to one or more embodiments of the present disclosure.

Referring to FIG. 7 in addition to FIGS. 1-6, the anode electrode AE may have a three-layer structure. For example, the anode electrode AE may include a first layer A1, a second layer A2, and a third layer A3. The first layer A1, the second layer A2, and the third layer A3 of the anode electrode AE may include different materials.

As illustrated in FIG. 4, the first layer A1 of the anode electrode AE may be positioned on and in contact with the second via layer 127.

The first layer A1 may assist in electrically connecting the anode electrode AE to the second connection electrode CNE2.

The first layer A1 may include a metal with high electrical conductivity. As an example, the first layer A1 may include aluminum (Al).

The second layer A2 of the anode electrode AE may be positioned on and in contact with the first layer A1.

The second layer A2 may assist in ensuring that the light emitted from the light-emitting layer EL is absorbed rather than reflected by the anode electrode AE. For example, the second layer A2 may include a material having a relatively high light absorptivity and a relatively low light reflectivity. In one or more embodiments, the second layer A2 may be black.

The second layer A2 may include a material in which tantalum (Ta) or tantalum oxide (Ta₂O₅) is added to molybdenum oxide (MoOₓ). For example, the second layer A2 may include molybdenum tantalum oxide (MoTaOₓ).

In one or more embodiments, the second layer A2 may have high electrical conductivity characteristics due to tantalum (Ta). As an example, in the second layer A2, an atomic percentage of tantalum (Ta) may range from 10 at% to 12 at%. For example, if (e.g., when) the atomic percentage of tantalum (Ta) has a value below the above-mentioned range, the anode electrode AE may have a high resistivity value, and if (e.g., when) it has a value above the above-mentioned range, it may cause manufacturing defects due to a high amount of excess particles. Unless indicated otherwise, “resistivity” refers to bulk resistivity (Ω·cm); values may be provided in μΩ·cm for convenience (1 Ω·cm = 10⁶ μΩ·cm).

In one or more embodiments, the resistivity value of the second layer A2 may be less than or equal to 1.0x10⁴ μΩ·cm (i.e., 1×10⁻² Ω·cm). For example, the second layer A2 may exhibits a resistivity of ≤ 1.0×10⁴ μΩ·cm (i.e., ≤ 1×10⁻² Ω·cm).

In one or more embodiments, the third layer A3 may be positioned on and in contact with the second layer A2.

The third layer A3 may have high transmittance characteristics. Accordingly, the light emitted from the light-emitting layer EL may be to transmit through the third layer A3 and be absorbed in the second layer A2. As an example, the third layer A3 may have a transmittance of 80% or more in the visible light range (e.g., a wavelength range of 380 nm to 700 nm).

In one or more embodiments, the third layer A3 may have hole injection characteristics.

The third layer A3 may include a transparent conductive material. As an example, the third layer A3 may include indium tin oxide (ITO).

For example, the anode electrode AE according to one or more embodiments may have a structure in which aluminum (Al), molybdenum tantalum oxide (MoTaOx, MTO), and indium tin oxide (ITO) are in contact with each other and stacked.

In one or more embodiments, the pixel-defining layer 159 may have characteristics of relatively high light absorption and relatively low light reflectance. Therefore, the pixel-defining layer 159 may be to absorb light emitted toward the pixel-defining layer 159 among the light emitted from the light-emitting layer EL. As an example, the pixel-defining layer 159 may have a black color.

The pixel-defining layer 159 may include an organic material. As an example, the pixel-defining layer 159 may be formed as an organic film such as an acryl resin, an epoxy resin, a phenolic resin, a polyamide resin, or a polyimide resin. In one or more embodiments, the pixel-defining layer 159 may include a black pigment and/or black dye to reduce reflection of external light and to prevent or reduce color mixing. For example, the pixel-defining layer 159 may include carbon black.

In one or more embodiments, the pixel-defining layer 159 may be in contact with and cover an edge of an upper surface b3 of third layer A3 of the anode electrode AE, and may be in contact with and cover a side surface a1 of the first layer A1, a side surface a2 of the second layer A2, and a side surface a3 of the third layer A3.

The first portion Ea included in the light-emitting layer EL may be in contact with the third layer A3 of the anode electrode AE. Accordingly, the first portion Ea included in the light-emitting layer EL may have stable hole injection and movement characteristics.

The second portion Eb included in the light-emitting layer EL may be a portion from which light is emitted. The light emitted from the second portion Eb may be emitted in various directions, such as a direction toward the cathode electrode CE, a direction toward the anode electrode AE, and a direction toward the pixel-defining layer 159.

The third portion Ec included in the light-emitting layer EL may be in contact with the cathode electrode CE. Accordingly, the third portion Ec included in the light-emitting layer EL may have electron injection and movement characteristics. As these features are described above, redundant descriptions may not be provided.

In one or more embodiments, the cathode electrode CE may be a transmissive thin film electrode including a metal. For example, the cathode electrode CE may be a transparent electrode. As an example, the cathode electrode CE may have a transmittance of 80% or more in the visible light range (e.g., a wavelength range of 380 nm to 700 nm).

The cathode electrode CE may include at least one of a transparent conductive oxide (TCO), a metal oxide composite structure, or a metal material. As an example, if (e.g., when) the cathode electrode CE includes a metal material, a thickness of the cathode electrode CE may be formed to be 10 nanometers or less.

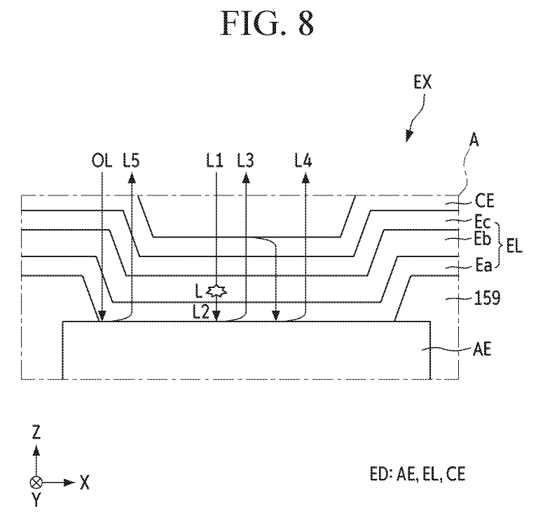

FIG. 8 is an enlarged cross-sectional view of the area A in FIG. 4 as a comparative example.

Referring to FIGS. 7 and 8, an anode electrode AE included in the comparative example EX may have a relatively high reflectivity. As an example, the anode electrode AE of the comparative example EX may be a metal layer including a metal such as silver (Ag), magnesium (Mg), aluminum (Al), platinum (Pt), palladium (Pd), gold (Au), nickel (Ni), neodymium (Nd), iridium (Ir), chromium (Cr), or a compound thereof.

In addition, a cathode electrode CE included in the comparative example EX may have semi-transmissive characteristics. As an example, the cathode electrode CE included in the comparative example EX may have a transmittance in the range of approximately 40% to 60% in the visible light range (e.g., a wavelength range of 380 nm to 700 nm).

As an example, the cathode electrode CE of the comparative example EX may include silver (Ag), magnesium (Mg), copper (Cu), aluminum (Al), lithium (Li), calcium (Ca), ytterbium (Yb), platinum (Pt), palladium (Pd), gold (Au), nickel (Ni), neodymium (Nd), iridium (Ir), chromium (Cr), molybdenum (Mo), titanium (Ti), or a compound or mixture thereof, for example, a mixture of silver (Ag) and magnesium (Mg), and may be semi-permeable by having a thickness of approximately tens to hundreds of angstroms.

A light-emitting element ED of the comparative example EX may have a micro-cavity (or thin-film resonance) structure by adjusting a distance between the anode electrode AE and the cathode electrode CE.

Accordingly, first light L1 among light L generated from the light-emitting layer EL included in the comparative example EX may be to transmit through the cathode electrode CE having the semi-transmissive characteristics and be emitted in the third direction (Z-axis direction). In addition, some of the first light L1 may be absorbed or reflected by the cathode electrode CE.

Second light L2 among the light L generated from the light-emitting layer EL included in the comparative example EX may be emitted in a direction toward the anode electrode AE, and be then converted into reflected light L3 at an interface of the anode electrode AE, and may be emitted in the third direction (Z-axis direction) by transmitting through the cathode electrode CE. In addition, some of the reflected light L3 may be reflected at an interface of the cathode electrode CE having the semi-transmissive characteristics, and a portion of the reflected light L3 reflected at the interface of the cathode electrode CE may be converted into reflected light L4 at the interface of the anode electrode AE, and may be emitted in the third direction (Z-axis direction) by being transmitted through the cathode electrode CE.

To explain again, the light L generated from the light-emitting layer EL included in the comparative example EX may be emitted toward the front due to the micro-cavity effect. Accordingly, a display device of the comparative example EX may have relatively strong frontal light intensity, and luminance and color tone at a side surface may have a relatively large deviation compared to a front surface. Therefore, the display device of the comparative example EX may have frontal efficiency, but low side viewing angle (white angular dependence (WAD)) characteristics.

In addition, in the display device of the comparative example EX, external light OL absorbed from the outside of the display device may be converted into reflected light L5 at the interface of the anode electrode AE, and may be emitted in the third direction (Z-axis direction) by transmitting through the cathode electrode CE. Therefore, the display device of the comparative example EX may separately include a polarizing optical film for reducing reflection of external light.

For convenience of explanation, the path of light traveling in one side and the other side in the third direction (Z-axis direction) is illustrated and then described, but the light emitted from the light-emitting layer EL may travel in all directions.

Recently, as the display devices 10 applied to various electronic devices are increasing, a display device may be desired or required that includes characteristics including a relatively wide emission angle and small deviation in luminance and color tone between the front and side surfaces, rather than characteristics that amplifies the intensity of light emitted to the entire surface.

Therefore, the display device 10 according to one or more embodiments may minimize or reduce reflection of light emitted to a lower portion of the light-emitting layer EL by applying the anode electrode AE having low reflection and high absorption characteristics and the pixel-defining layer 159 having low reflection and high absorption characteristics. In addition, the display device 10 according to one or more embodiments may minimize or reduce reflection of light at the interface of the cathode electrode CE by applying the transparent cathode electrode CE having high transmissive characteristics. For example, the display device 10 according to one or more embodiments may include a completely non-resonant structure by forming a blackening layer below the light-emitting layer EL and concurrently (e.g., simultaneously) forming a transparent electrode over the light-emitting layer EL.

Referring again to FIG. 7, in one or more embodiments, the first light L1 among the light L generated from the second portion Eb of the light-emitting layer EL may be emitted by transmitting through the transparent cathode electrode CE. As the display device 10 according to one or more embodiments includes the transparent cathode electrode CE, reflection, absorption, interference, and/or the like by the cathode electrode CE may be minimized or reduced.

As the display device 10 according to one or more embodiments includes the non-resonant structure, the first light L1 may be emitted with a similar intensity in the third direction (Z-axis direction) and in an inclined direction between the first direction (X-axis direction) or the second direction (Y-axis direction) and the third direction (Z-axis direction).

In one or more embodiments, the second light L2 among the light L generated from the second portion Eb of the light-emitting layer EL may be emitted in a direction toward the anode electrode AE.

As the third layer A3 of the anode electrode AE included in the display device 10 according to one or more embodiments includes the transparent material, the second light L2 may directly transmit through the third layer A3. The second light L2 may be mostly absorbed without being reflected by the second layer A2 of the anode electrode AE having low reflection and high absorption characteristics. Accordingly, the display device 10 according to one or more embodiments may minimize or reduce reflection, absorption, interference, and/or the like by the anode electrode AE.

In one or more embodiments, the external light OL absorbed from the outside of the display device 10 may be mostly absorbed by the second layer A2 of the anode electrode AE. Therefore, the display device 10 according to one or more embodiments may not have a separate polarizing optical film.

In process of manufacturing the display device 10, the first layer A1, the second layer A2, and the third layer A3 may be formed by a photo pattern process. Accordingly, the first layer A1, the second layer A2, and the third layer A3 may have a conductive pattern shape.

In process of manufacturing the display device 10, the second layer A2 may be removed by the same etching process as the first layer A1. Accordingly, the side surface a2 of the second layer A2 and the side surface a1 of the first layer A1 may be positioned on the same line. For example, the side surface a2 of the second layer A2 and the side surface a1 of the first layer A1 may be aligned.

In one or more embodiments, the side surface a3 of the third layer A3 may be positioned on the same line as the side surface a2 of the second layer A2 and the side surface a1 of the first layer A1, but the present specification is not limited thereto.

In one or more embodiments, a thickness H1 of the first layer A1 of the anode electrode AE may be greater than a thickness H2 of the second layer A2, and a thickness H3 of the third layer A3 may be equal to or smaller than the thickness H2 of the second layer A2.

In one or more embodiments, a thickness Hae of the anode electrode AE may have a value greater than or equal to 450 Angstroms and smaller than or equal to 800 Angstroms. A detailed description thereof will be provided later.

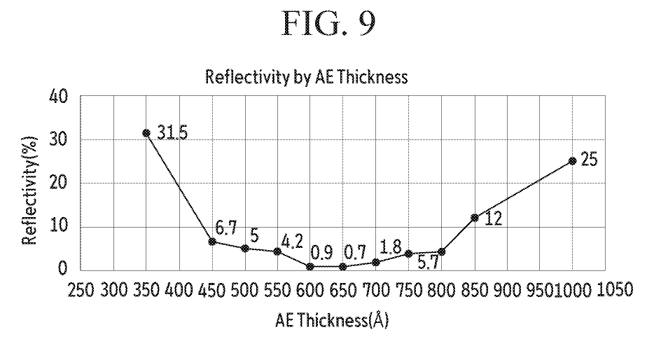

FIG. 9 is a graph illustrating light reflectivity based on the thickness of an anode electrode according to one or more embodiments of the present disclosure.

Referring to FIG. 9 in addition to FIGS. 1-8, an X-axis of the illustrated graph represents a thickness (e.g., the thickness Hae of FIG. 7) of the anode electrode AE included in the display device 10, and a Y-axis of the illustrated graph represents a reflectivity (%) of the anode electrode. The above-described reflectivity (%) was measured using a reflectivity measuring device.

The anode electrode AE according to one or more embodiments has a reflectivity of 6.7% if (e.g., when) the thickness Hae of the anode electrode AE is 450 angstroms, and a reflectivity of 5.7% if (e.g., when) the thickness Hae of the anode electrode AE is 800 angstroms. For example, the anode electrode AE according to one or more embodiments may have a reflectivity of 10% or less if (e.g., when) the thickness Hae of the anode electrode AE has a value of 450 angstroms or more and 800 angstroms or less. The thickness range described above may have a process error range of 10%.

For example, the X-axis represents the total anode thickness Hae and the Y-axis represents hemispherical reflectance at 550 nm unless otherwise stated. The anode electrode shows reflectivity of 6.7% at Hae = 450 Å and 5.7% at Hae = 800 Å.

For example, if (e.g., when) the thickness Hae of the anode electrode AE is smaller than 400 Angstroms or greater than 850 Angstroms, the anode electrode AE may have a reflectivity of 10% or more. Therefore, the thickness Hae of the anode electrode AE may be formed within the above-described range.

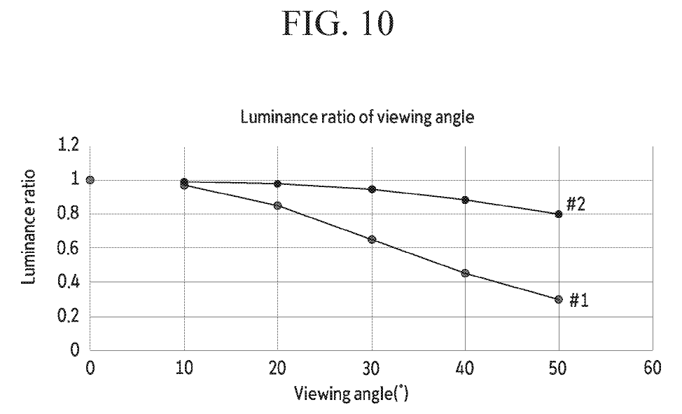

FIG. 10 is a graph illustrating a ratio of efficiency for each side angle relative to the frontal efficiency of the display device according to one or more embodiments of the present disclosure. For example, FIG. 10 is a graph illustrating luminance ratio (relative to 0°) versus viewing angle.

Referring to FIG. 10 in addition to FIGS. 1-9, the illustrated graph is a graph illustrating a luminance ratio measured at each viewing angle based on the front, when the front of the display device 10 is defined as 0° and a value of luminance measured at the front is defined as 1. The X-axis of the illustrated graph represents the viewing angle (°) based on the front of the display device 10, and the Y-axis of the graph represents the luminance ratio measured for each angle.

In the illustrated graph, Sample 1 (#1) is a measurement value of the display device of the comparative example EX illustrated in FIG. 8, and Sample 2 (#2) is a measurement value of the display device 10 illustrated in FIGS. 4-7.

The display device of the comparative example EX had a luminance ratio of approximately 0.82 times at a viewing angle of 20° based on the front luminance. In addition, the display device of the comparative example EX had a luminance ratio of approximately 0.62 relative to the front luminance at a viewing angle of 30°, had a luminance ratio of approximately 0.42 relative to the front luminance at a viewing angle of 40°, and had a luminance ratio of approximately 0.3 relative to the front luminance at a viewing angle of 50°.

In contrast, the display device according to one or more embodiments had a luminance ratio of approximately 0.8 relative to the front luminance at a viewing angle of 50°. In addition, the display device according to one or more embodiments had a luminance ratio of approximately 0.95 relative to the front luminance at a viewing angle of 30° and had a luminance ratio of approximately 0.9 relative to the front luminance at a viewing angle of 40°.

In one or more embodiments, the display device 10 according to one or more embodiments may include a non-resonant structure by forming black layers (the anode electrode AE and the pixel-defining layer 159) having low reflection and high absorption characteristics on the lower portion of the light-emitting layer EL and forming the high transmissive transparent layer (the cathode electrode CE) on the upper portion of the light-emitting layer EL, and may thus include a relatively wide emission angle. Thus, the display device 10 according to one or more embodiments may improve the luminance deviation based on the viewing angle (e.g., may decrease the luminance deviation).

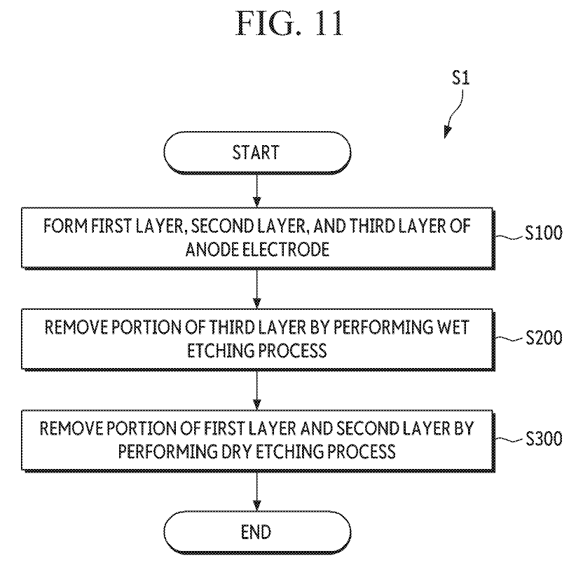

FIG. 11 is a flowchart illustrating a method for manufacturing an anode electrode according to one or more embodiments of the present disclosure.

Referring to FIG. 11 in addition to FIGS. 1-10, a method (S1) for manufacturing an anode electrode AE included in the display device according to one or more embodiments may include a step (e.g., act or task) (S100) of forming a first layer, a second layer, and a third layer of the anode electrode, a step (e.g., act or task) (S200) of removing a portion of the third layer by performing a wet etching process, and a step (e.g., act or task) (S300) of removing the first layer and the second layer by performing a dry etching process.

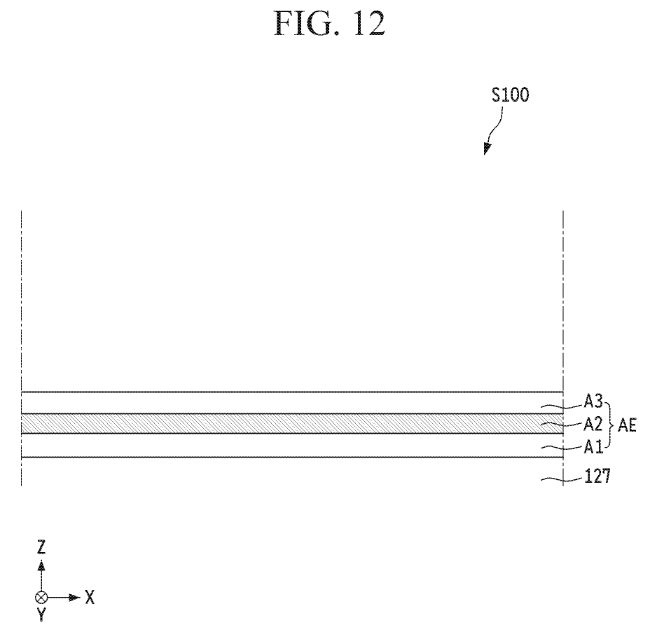

FIG. 12 is a cross-sectional view for describing step (e.g., act or task) S100 of FIG. 11 according to one or more embodiments of the present disclosure.

The step (e.g., act or task) (S100) of forming the first layer, the second layer, and the third layer of the anode electrode will be described with reference to FIG. 12 in addition to FIGS. 1-11.

First, the first layer A1, the second layer A2, and the third layer A3 of the anode electrode AE are formed on the second via layer 127. The first layer A1, the second layer A2, and the third layer A3 may be formed across the entirety of the second via layer 127 as a single, continuous layer.

In the present process, the process of forming the first layer A1, the second layer A2, and the third layer A3 may be performed by a deposition process including at least one of the above-described metal materials.

In the present process, the first layer A1, the second layer A2, and the third layer A3 may include different materials. As an example, the first layer A1 may include aluminum (Al), the second layer A2 may include molybdenum tantalum oxide (MoTaOx, MTO), and the third layer A3 may include indium tin oxide (ITO). As these features are described above, redundant descriptions may not be provided.

In one or more embodiments, a thin film transistor layer 130 including the second via layer 127 may be positioned on the substrate 110, and a detailed structure of the thin film transistor layer 130 may be the same as that illustrated in FIG. 4.

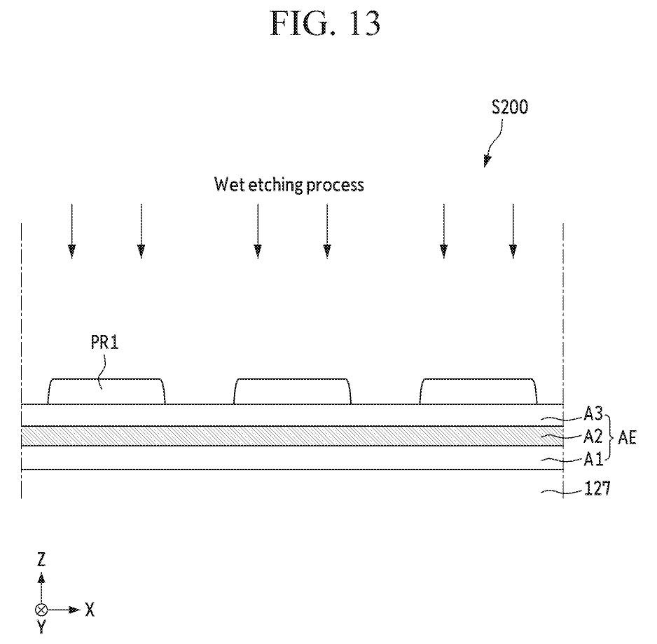

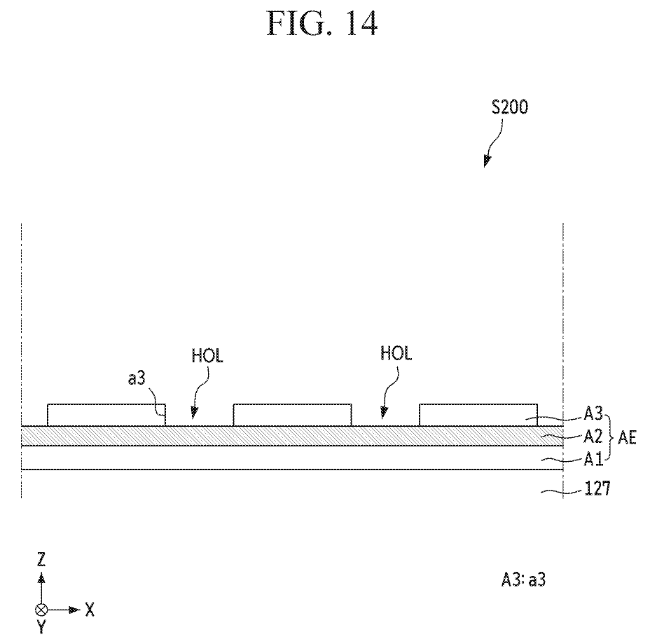

FIGS. 13 and 14 are cross-sectional views for describing step (e.g., act or task) S200 of FIG. 11, according to one or more embodiments of the present disclosure.

The step (e.g., act or task) (S200) of removing a portion of the third layer by performing the wet etching process will be described with reference to FIGS. 13 and 14 in addition to FIGS. 1-12.

Next, a photoresist PR1 is formed on the third layer A3, and a wet etching process is performed.

As an example, the wet etching process may be performed using liquid chemical solutions such as diluted hydrofluoric acid solution, nitric acid solution, tetramethylammonium hydroxide solution, potassium hydroxide solution, and/or the like.

In the present process, the third layer A3 that does not overlap the photoresist PR1 may be selectively removed, thereby forming a hole HOL as illustrated in FIG. 14. The second layer A2 overlapping the hole HOL may be exposed.

In the present process, the third layer A3 of the anode electrode AE may be formed as a plurality of conductive patterns, and the plurality of conductive patterns may be spaced and/or apart (e.g., spaced apart or separated) with the hole HOL interposed therebetween.

In the present process, the third layer A3 of the anode electrode AE may have a side surface a3 facing the hole HOL.

In one or more embodiments, the photoresist PR1 may be removed through an ashing process.

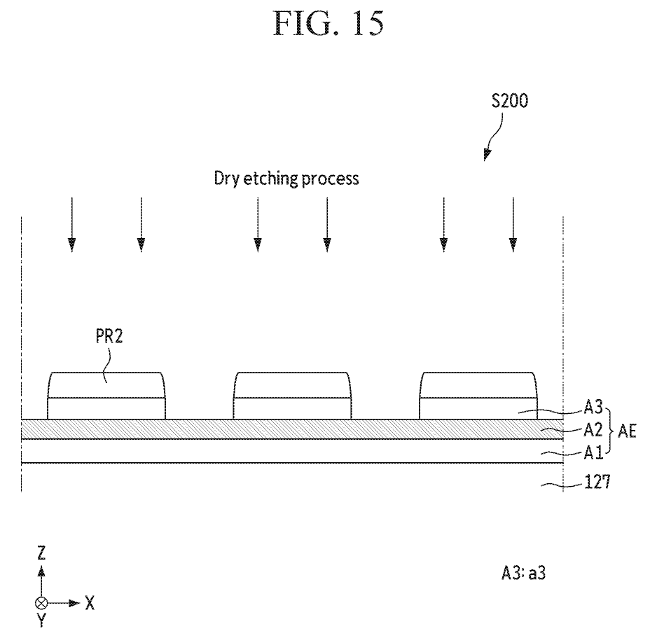

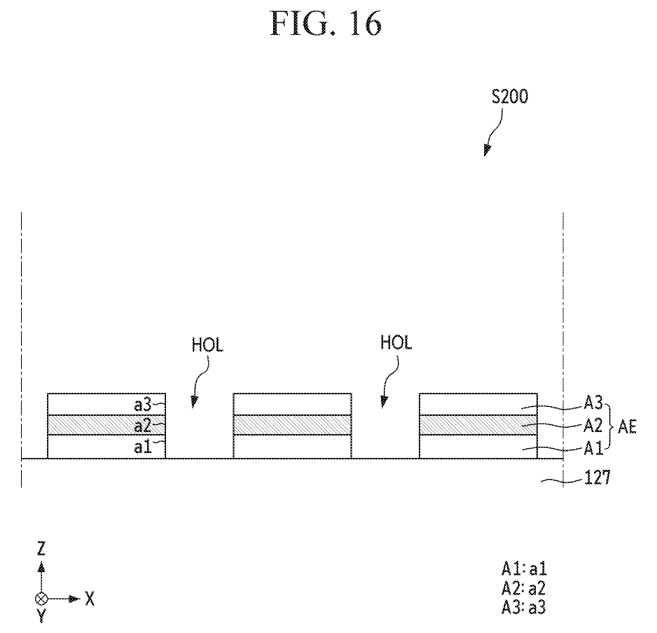

FIGS. 15 and 16 are cross-sectional views for describing step (e.g., act or task) S300 of FIG. 11, according to one or more embodiments of the present disclosure.

The step (e.g., act or task) (S300) of removing the first layer and the second layer by performing the dry etching process will be described with reference to FIGS. 15 and 16 in addition to FIGS. 1-14.

Next, a photoresist PR2 may be formed on the third layer A3, and a dry etching process is performed. In the present process, a plurality of photoresists PR2 may be formed and spaced and/or apart (e.g., spaced apart or separated) with the hole HOL interposed therebetween.

As an example, the dry etching process may be performed through a reactive ion etching (RIE) process using reactive gases such as CHF₃, CH₃F, CH₂F₂, CHF₆, CF₄, C₂F₆, and C₃F₆, and sputtering gases such as Ar, and O₂/Ar. In such embodiments, an inductively coupled plasma (ICP) source or a capacitively coupled plasma (CCP) source may be used as a plasma source.

In the present process, the first layer A1 and the second layer A2 that do not overlap the photoresist PR2 may be removed concurrently (e.g., simultaneously or at once). Accordingly, the first layer A1 and the second layer A2 may have side surfaces a1 and a2 facing the hole HOL.

In the present process, as the first layer A1 and the second layer A2 are removed concurrently (e.g., simultaneously or at once) by the same process, the side surface a1 of the first layer A1 and the side surface a2 of the second layer A2 may be positioned on the same line (e.g., may be aligned).

In one or more embodiments, the side surface a3 of the third layer A3 may be positioned on the same line as the side surface a1 of the first layer A1 and the side surface a2 of the second layer A2, but the present disclosure is not limited thereto.

In one or more embodiments, the photoresist PR2 may be removed through an ashing process.

In this way, the anode electrode AE according to one or more embodiments may be formed. The display device 10 according to one or more embodiments may have ease of manufacture by removing the first layer A1 and the second layer A2 of the anode electrode AE concurrently (e.g., simultaneously or at once)in substantially the same process.

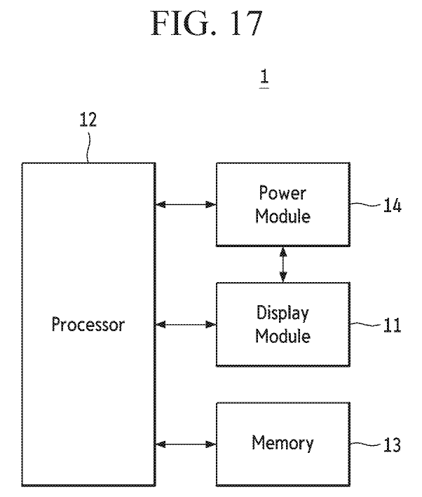

FIG. 17 is a block diagram of an electronic device according to one or more embodiments of the present disclosure.

Referring to FIG. 17 in addition to FIGS. 1-16, the display device 10 according to one or more embodiments may be applied to one or more suitable electronic devices 1. The electronic device 1 according to one or more embodiments may include the display device 10 described above, and may further include at least one a module or device having additional functions in addition to the display device 10.

The electronic device 1 according to one or more embodiments may include a display module 11, a processor 12, a memory 13, and a power module 16.

The processor 12 may include at least one of a central processing unit (CPU), an application processor (AP), a graphic processing unit (GPU), a communication processor (CP), an image signal processor (ISP), and/or a controller.

Data information for an operation of the processor 12 or the display module 11 may be stored in the memory 13. When the processor 12 executes an application stored in the memory 13, image data signals and/or input control signals may be transmitted to the display module 11, and the display module 11 may process the provided signals and output image information through a display screen.

The power module 16 may include a power supply module, such as a power adapter or a battery device, and a power conversion module that converts power supplied by the power supply module to generate power for the operation of the electronic device 1.

At least one of the components of the electronic device 1 described above may be included in the display device 10 according to the above-described embodiments. In addition, some of the individual modules functionally included within one module may be included within the display device, while others may be provided separately from the display device. For example, the display device may include the display module 11, and the processor 12, the memory 13, and the power module 16 may be provided in the form of other devices within the electronic device 1 other than the display device.

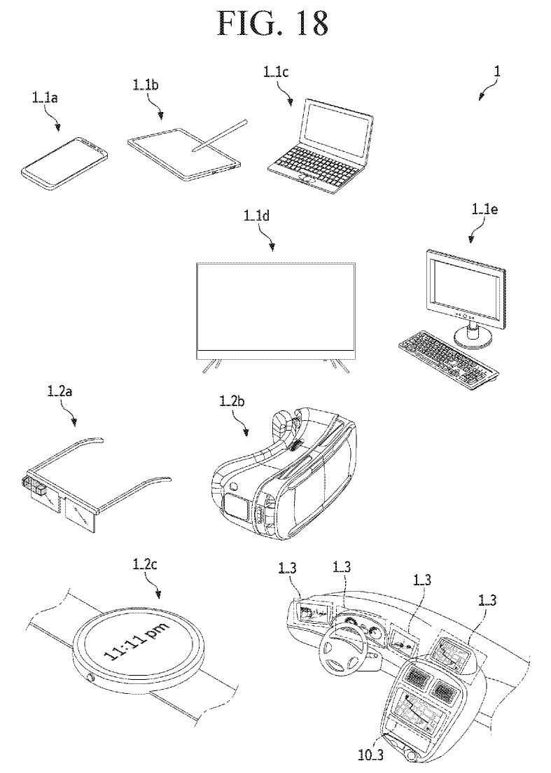

FIG. 18 illustrates schematic diagrams of electronic devices according to one or more embodiments of the present disclosure.

Referring to FIG. 18, one or more electronic devices 1 to which the display device 10 according to one or more embodiments may be applied may include not only an image display electronic device such as a smart phone 1_1a, a tablet PC 1_1b, a laptop 1_1c, a TV 1_1d, and/or a desk monitor 1_1e, but also a wearable electronic device including a display module such as a smart glasses 1_2a, a head mounted display 1_2b, a smart watch 1_2c, and/or the like, or a vehicle electronic device 1_3 including a display module such as a Center Information Display (CID), a room mirror display, and/or the like, arranged on a vehicle’s instrument panel, center fascia, or dashboard.

The use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ± 30%, 20%, 10%, 5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic device, device for manufacturing the display device, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate;
an anode electrode on the substrate and comprising a first layer, a second layer, and a third layer sequentially stacked;
a pixel-defining layer covering an edge of the anode electrode and defining a light-emitting opening;
a light-emitting layer on the anode electrode and the pixel-defining layer; and
a cathode electrode on the light-emitting layer,
wherein the first layer of the anode electrode comprises aluminum, and
wherein the second layer comprises molybdenum tantalum oxide.

2. The display device of claim 1, wherein an atomic percentage of tantalum included in the second layer is in a range of 10 at% to 12 at%.

3. The display device of claim 2, wherein the second layer has a reflectivity of 10% or less in a visible light range of 380 nanometers to 700 nanometers.

4. The display device of claim 3, wherein the third layer is in contact with and on the second layer, and wherein the third layer comprises indium tin oxide.

5. The display device of claim 4, wherein the third layer has a transmittance of 80% or more in the visible light range of 380 nanometers to 700 nanometers.

6. The display device of claim 4, wherein the anode electrode has a structure in which aluminum, molybdenum tantalum oxide, and indium tin oxide are in contact with each other and stacked.

7. The display device of claim 1, wherein the pixel-defining layer comprises a black dye or a black pigment.

8. The display device of claim 7, wherein the pixel-defining layer is in contact with the third layer of the anode electrode, and
wherein the third layer is in contact with the light-emitting layer at a portion overlapping the light-emitting opening.

9. The display device of claim 8, wherein a side surface of the first layer, a side surface of the second layer, and a side surface of the third layer are in contact with and covered by the pixel-defining layer.

10. The display device of claim 9, wherein the side surface of the first layer and the side surface of the second layer are positioned on the same line.

11. The display device of claim 1, wherein the cathode electrode comprises a transparent conductive material, and
wherein the cathode electrode has a transmittance of 80% or more in a visible light range of 380 nanometers to 700 nanometers.

12. The display device of claim 1, wherein the second layer has a resistivity value of 1.0x10⁴ μΩ·cm or less.

13. The display device of claim 1, wherein the anode electrode has a thickness of 450 Angstroms to 800 Angstroms.

14. A method comprising:
forming a first layer, a second layer, and a third layer of an anode electrode;
removing a portion of the third layer by performing a wet etching process; and
removing a portion of the first layer and the second layer by performing a dry etching process,
wherein the first layer comprises aluminum,
wherein the second layer comprises molybdenum tantalum oxide,
wherein the third layer comprises indium tin oxide, and
wherein the method is a method for manufacturing a display device.

15. The method of claim 14, wherein in the removing of the portion of the first layer and the second layer by performing the dry etching process,
the first layer and the second layer are removed concurrently, and
a side surface of the first layer and a side surface of the second layer are positioned on the same line.

16. An electronic device comprising:
at least one display device comprising a substrate; and
at least one of a display module, a processor, a memory, or a power module connected to the display device,
wherein the at least one display device comprises:
an anode electrode on the substrate and comprising a first layer, a second layer, and a third layer sequentially stacked;
a pixel-defining layer covering an edge of the anode electrode and defining a light-emitting opening;
a light-emitting layer on the anode electrode and the pixel-defining layer; and
a cathode electrode on the light-emitting layer,
wherein the first layer of the anode electrode comprises aluminum, and wherein the second layer comprises molybdenum tantalum oxide.

17. The electronic device of claim 16, wherein an atomic percentage of tantalum in the second layer is 10 at% to 12 at%.

18. The electronic device of claim 17, wherein the second layer has a reflectivity of 10% or less in a visible light range of 380 nanometers to 700 nanometers.

19. The electronic device of claim 18, wherein the anode electrode has a structure in which aluminum, molybdenum tantalum oxide, and indium tin oxide are in contact with each other and stacked.

20. The electronic device of claim 16, wherein the pixel-defining layer comprises carbon black, and
wherein a side surface of the first layer, a side surface of the second layer, and a side surface of the third layer are in contact with the pixel-defining layer.
